(19) United States
(12) Patent Application Publication
(10) Pub. No.: US 2008/0296567 A1
(43) Pub. Date: Dec. 4, 2008

(54) METHOD OF MAKING THIN FILM TRANSISTORS COMPRISING ZINC-OXIDE-BASED SEMICONDUCTOR MATERIALS

(76) Inventors: Lyn M. Irving, Rochester, NY (US); David H. Levy, Rochester, NY (US); Andrea C. Childs, Webster, NY (US)

Correspondence Address: Andrew J. Anderson;Patent Legal Staff, Eastman Kodak Company, 343 State Street, Rochester, NY, 14650-2201, US

(21) Appl. No.: 11/757,549

(22) Filed: Jun. 4, 2007

(51) Int. Cl. H01L 29/22; H01L 21/34

(52) U.S. Cl. 257/43; 438/104; 257/E29.094; 257/E21.46

(57) ABSTRACT

A method of making a thin film transistor comprising a zinc-oxide-containing semiconductor material and spaced apart first and second electrodes in contact with the material. The co-generation of high quality zinc oxide semiconductor films and contact electrodes is obtained, at low temperatures, using non-vacuum conditions, silver nanoparticles are deposited to form the source and drain and, upon heating, converted to conducting metal. Such an in-situ formation of the silver metal/zinc oxide interface provides superior transistor activity compared to evaporated silver.

### FIELD OF THE INVENTION

The present invention relates to a method of making thin film transistors in which a colloidal solution of silver nanoparticles is printed onto a zinc-oxide-based semiconductor film. Such thin film transistors can be used in electronic devices, particularly in displays in which low temperature processes of making the thin film transistors are advantageous.

### BACKGROUND OF THE INVENTION

For applications in which a transistor needs to be applied to a substrate, a thin film transistor is typically used. Thin film transistors (TFTs) are widely used as switching elements in electronics, for example, in active-matrix liquid-crystal displays, smart cards, and a variety of other electronic devices and components thereof. The thin film transistor (TFT) is an example of a field effect transistor (FET). The best-known example of an FET is the MOSFET (Metal-Oxide-Semiconductor-FET), today's conventional switching element for high-speed applications. A critical step in fabricating the thin film transistor involves the deposition of a semiconductor onto the substrate. Presently, most thin film devices are made using vacuum deposited amorphous silicon as the semiconductor.

Amorphous silicon as a semiconductor for use in TFTs still has its drawbacks. The deposition of amorphous silicon, during the manufacture of transistors, requires relatively difficult or complicated processes such as plasma enhanced chemical vapor deposition and high temperatures (about 360° C.) to achieve the electrical characteristics sufficient for display applications. Such high processing temperatures disallow deposition on substrates made of certain plastics that might otherwise be desirable for use in applications such as flexible displays.

In the past decade, various materials have received attention as a potential alternative to amorphous silicon for use in semiconductor channels of thin film transistors. Semiconductor materials are desirable that are simpler to process, especially those that are soluble in organic or aqueous solvents and, therefore, capable of being applied to large areas by relatively simple processes, such as spin coating, dip coating, microcontact printing, or ink jet application. Semiconductor materials that can be deposited at lower temperatures would open up a wider range of substrate materials, including plastics, for flexible electronic devices. Furthermore, additive solution processes have the opportunity to reduce materials costs by only applying semiconductor materials where they are needed.

Thus, thin film transistors made of coatable semiconductor materials can be viewed as a potentially important technology for circuitry in various electronic devices or components such as display backplanes, portable computers, pagers, memory elements in transaction cards, and identification tags, where important considerations are ease of fabrication, including roll-to-roll processing and/or moderate operating temperatures.

This, in turn, has fueled an interest in discovering new semiconductor materials. Organic semiconductors comprise one broad class of low-temperature alternative semiconductor materials that have been the subject of considerable research efforts. However, most organic semiconductors generally have inferior or problematic electronic properties compared to amorphous silicon for use in transistor devices. For example, organic materials may tend to degrade in normal atmospheric conditions. In contrast, inorganic semiconductors tend to be more stable. Consequently, an inorganic semiconductor that is compatible with temperature-sensitive substrates and that has electronic properties equivalent to amorphous silicon would enable electronics for a variety of flexible substrates.

The discovery of new inorganic semiconductors has also been the subject of considerable research efforts. For example, metal oxide semiconductors are known that, for example, constitute zinc oxide, indium oxide, tin oxide, or cadmium oxide deposited with or without additional doping elements including transition metals such as aluminum. Such semiconductor materials, which are transparent, can have an additional advantage for certain applications, as discussed below.

Various processes for making zinc oxide films have been disclosed, both high temperature and low temperature processes, including radio-frequency magnetron sputtering or modified reactive planar magnetron sputtering.

Ohya et al (Japanese Journal of Applied Physics, Part 1, January 2001, vol. 40, no. 1, pages 297-8) disclose a thin film transistor of ZnO fabricated by chemical solution deposition.

Transparent conducting oxides are reviewed in the August 2000 issue of the Materials Research Bulletin, Volume 25 (8) 2000, devoted to materials and properties of transparent conducting oxide compounds.

One low temperature process for deposition of such oxide semiconductors is disclosed in US Patent Application Publication No. 2004/0127038 to Carcia et al. This publication discloses a semiconductor deposition process that uses magnetron sputtering of a metal oxide (ZnO, In₂O₃, SnO₂, CdO) or metal (Zn, In, Sn, Cd) target in an atmosphere with a controlled partial pressure of oxygen in an inert gas. This is a low temperature process that is compatible with temperature sensitive substrates and components, for example, drive circuits for displays on flexible, polymer substrates. The field effect transistors of Carcia et al. are based on a nominally undoped metal oxide semiconductor that must be deposited using physical vapor deposition or chemical vapor deposition, preferably rf (radio frequency) magnetron sputtering. The thin film transistor structure described by Carcia et al. involved deposition of the semiconductor over a source and drain. Ti—Au source and drain electrodes (10 nm Ti followed by 100 nm Au), 200 micrometer side with a 20 micrometer gap were deposited and patterned directly on the a thermal silicon oxide layer by traditional photolithography. Zinc oxide or Indium oxide about 100 nm thick was then sputtered between source and drain electrons using a shadow mask.

Japanese Kokai 2004-349583 discloses a method of producing a thin film transistor in which a dispersion of zinc-oxide nanoparticles is ink-jetted to form the semiconducting channel.

US Patent Application Publication No. 2004/0127038 discloses a method to produce high quality zinc-oxide thin film transistors using sputtering as a vacuum deposition method.

Steven K. Volkman et al., “A novel transparent air-stable printable n-type semiconductor technology using ZnO nanoparticles,” 2004 IEEE International Electron Device meeting Technical Digest, pp. 769, 2004, discloses a method for producing thin film transistors using organically stabilized zinc-oxide nanoparticles. The disclosed process involves an exposure to a temperature of 400° C. or plasma hydrogenation.

U.S. Pat. No. 6,689,186 to Hampden-Smith et al. discloses silver particles in solution for use in electronically conductive portions of electronic products. It does not, however, relate to zinc-oxide-based thin film transistors.

A potential problem with the development of new thin film semiconductors is their manufacturability and their compatibility with other parts of transistors. In particular, the manufacture of transistors requires the building up of components, in which subsequent layers must effectively interact with previously formed layers. Inter-surface adhesion or other interfacial properties between different layers, particularly involving semiconductor thin films, are often critical in the effective functioning of transistors. The development of new thin film transistors may benefit from the use of improved materials and processes for their different layers or components.

### SUMMARY OF THE INVENTION

This invention relates to the generation of thin film transistors (TF) comprising high quality zinc-oxide-based semiconductor films and silver contact electrodes, at low temperature, using relatively low temperature and non-vacuum conditions. Improved interfacial contact for efficient charge injection into a zinc oxide film is achieved by using a silver nanoparticle for making a source/drain electrode for contact with a zinc-oxide-based semiconductor film, in fabrication. In a TFT structure, the contact (conducting) electrodes are commonly referred to as a source and a drain, for injecting a current into the zinc-oxide-based semiconductor. A capacitance charge injection scheme for controlling or modulating the source-drain current may be employed.

In particular, a preferred embodiment of the present invention is directed to a method of making a thin film transistor comprising a zinc oxide semiconductor, the method comprising:

(a) forming on a substrate, at a temperature of 300° C. or less, a zinc-oxide-based semiconductor thin film, wherein the thin film is formed from a material that is the reaction product of a first reactant, an organo-zinc precursor compound comprising both zinc and organic groups, and a second reactant, an inorganic compound comprising oxygen, wherein the thin film has a thickness of 5 to 150 nm;

(b) depositing, in a pattern, a colloidal solution of substantially pure silver-metal nanoparticles on the surface of the zinc-oxide-based semiconductor film, the substantially pure silver-metal nanoparticles having an average primary particles size of 5 to 100 nm, whereby the pattern is in the form of a source electrode and drain electrode; and

(c) annealing at a temperature of between 100° C. and 500° C. to convert the substantially pure silver-metal nanoparticles to a source electrode and a drain electrode, having a thickness of at least 500 Angstroms, of substantially pure silver.

Upon heat treatment, the silver nanoparticles are converted to conducting metal. The steps of the above method can be in any order, however.

Such formation of the silver-metal/zinc-oxide interface provides superior transistor activity compared to evaporated silver, including high mobility and high on/off ratio.

The zinc oxide semiconductor material can contain other metals capable of forming semiconducting oxides such as indium, tin, cadmium, and combinations thereof. Lower amounts of acceptor dopants can also be included. One aspect of the present invention is directed to a process for fabricating a thin film transistor, preferably by deposition of the n-channel semiconductor film followed by applying the silver metal electrodes onto a substrate, wherein the substrate temperature is at a temperature of no more than 300° C. during the deposition. In one embodiment, the silver nanoparticles are coated at room temperature, the coating step followed by an annealing step for, typically, one hour or less, at a substrate temperature of 300° C. or less. Laser annealing may be employed to allow the material to reach higher temperatures while maintaining relatively low substrate temperatures.

The invention is also directed to a transistor comprising with a zinc oxide semiconductor, preferably on a flexible substrate, made by the present process.

In a preferred embodiment, the zinc-oxide-based semiconductor materials are “n-type,” although, through the use of suitable dopants, p-type materials are also envisioned. The zinc-oxide-based semiconductor material can contain other metals capable of forming semiconducting oxides such as indium, tin, or cadmium, and combinations thereof. Minor amounts of acceptor dopants can also be included.

Semiconductor films made by the present method are capable of exhibiting, in the film form, stable threshold voltages and excellent field-effect electron mobility of greater than 0.01 cm²/Vs and on-off ratios of greater than 10⁴, in which performance properties are sufficient for use in a variety of relevant technologies, including active matrix display backplanes.

One embodiment of the present invention is directed to the use of such n-channel semiconductor films in thin film transistors each comprising spaced apart first and second contact means connected to an n-channel semiconductor film. A third contact means can be spaced from said semiconductor film by an insulator, and adapted for controlling, by means of a voltage applied to the third contact means, a current between the first and second contact means through said film. The first, second, and third contact means can correspond to a drain, source, and gate electrode in a field effect transistor.

### BRIEF DESCRIPTION OF THE DRAWINGS

The above and other objects, features, and advantages of the present invention will become more apparent when taken in conjunction with the following description and drawings wherein identical reference numerals have been used, where possible, to designate identical or analogous features that are common to the figures, and wherein:

FIG. 1 illustrates a cross-sectional view of a typical thin film transistor having a bottom-gate/bottom-contact configuration;

FIG. 2 illustrates a cross-sectional view of a typical thin film transistor having a bottom-gate/top-contact configuration;

FIG. 3 illustrates a cross-sectional view of a typical thin film transistor having a top-gate/bottom-contact structure;

FIG. 4 illustrates a cross-sectional view of a typical thin film transistor having a top-gate/top-contact structure;

FIG. 5 illustrates a typical active matrix pixel design comprising a select transistor and capacitor representing the capacitance due to display design; and

FIG. 6 illustrates a typical pixel layout comprising data lines, control lines, thin film transistors, and pixel conductor pads.

### DETAILED DESCRIPTION OF THE INVENTION

The present invention is directed to the co-generation of high quality zinc oxide based films and contact electrodes, at low temperatures, using organic-vapor-phase or solution-based methodologies involving essentially non-vacuum conditions. Improved interfacial contact for efficient charge injection into a zinc oxide film is achieved by using a nanoparticulate silver precursor as a source/drain electrode precursor for TFT fabrication. A silver nanoparticulate ink formulation is printed over a pre-existing zinc oxide film. Upon heat treatment, the nanoparticles are converted to conducting metal. Such an in-situ formation of the silver metal/zinc oxide interface provides superior transistor activity compared to evaporated silver.

In a preferred embodiment, a thin film transistor comprising a zinc-oxide-based semiconductor is made by:

(a) forming on a substrate, at a temperature of 300° C. or less, a zinc-oxide-based semiconductor film comprising a layer of a zinc-oxide-based material, wherein the layer is formed by depositing a zinc-oxide-based material that is the reaction product of a mixture of reactants comprising an organozinc precursor compound and a second reactant, for example a basic ionic compound when employing a solution methodology or water when employing an organic-vapor-phase methodology, wherein the film has a thickness of 10 to 150 nm;

(b) depositing a patterned coating comprising a colloidal solution of substantially pure silver-metal nanoparticles over the upper surface of the zinc-oxide-based semiconductor film, the substantially pure silver-metal nanoparticles having an average primary particles size of 5 to 100 nm, wherein a pattern for a source electrode and drain electrode is formed; and

(c) annealing the patterned coating at a temperature of between 100° C. and 500° C. to convert the substantially pure silver-metal nanoparticles to a source electrode and a drain electrode, having a thickness of at least 500 Angstroms, of substantially pure silver in which a zinc-oxide and silver interface is formed separated by a channel of zinc-oxide-based semiconductor material.

As indicated above, the source/drain contacts or terminals refer to the conducting terminals of a thin TFT, between which conduction occurs under the influence of an electric field. Designers often designate a particular source/drain terminal to be a “source” or a “drain” on the basis of the voltage to be applied to that terminal when the TFT is operated in a circuit.

The source electrode and drain electrode are separated from the gate electrode by at least the gate dielectric, while the zinc-oxide-based semiconductor layer can be over or under the source electrode and drain electrode. The source and drain electrodes are based on silver nanoparticles.

The colloidal solution of substantially pure silver-metal nanoparticles are preferably deposited as fluid droplets by inkjet printing. However, the silver-metal nanoparticles alternatively can be deposited by relief printing, gravure printing, screen printing, by flexography in which a roller picks up a coating of the colloidal solution and applies it on a mask, or the like.

The inkjet printhead can be a continuous or drop-on-demand inkjet printhead. In a conventional inkjet printhead, the method of inkjet printing the source and drain over a semiconductor film on a substrate element typically comprises: (a) providing an inkjet printhead that is responsive to digital data signals; (b) loading a first printhead with the colloidal solution of nanoparticles; (c) printing on the substrate using the colloidal solution in response to the digital data signals; and (d) annealing the printed substrate. After forming a patterned coating, it is annealed to convert the substantially pure silver-metal nanoparticles to a source electrode and a drain electrode, having a thickness of at least 500 Angstroms, preferably at least 0.05 microns, more preferably at least about 0.1 microns, preferably up to 5 microns.

The colloidal solution of substantially pure silver-metal nanoparticles is preferably a solution with up to 80% of an organic solvent. Preferably, the colloidal solution of substantially pure silver-metal nanoparticles is aqueous with less than 50%, by weight of total liquid carrier, of an organic solvent, more preferably less than 25% organic solvent and 50 to 100 percent water.

The vehicle for the silver nanoparticles should be selected to prevent complete dissolution of the underlying zinc oxide-based semiconductor film. It is specifically contemplated that partial dissolution of the zinc oxide semiconductor layer during the printing step may be desirable to form a high 20 quality contact. The zinc oxide-based semiconductor layer may be sparingly soluble in the colloidal solution of substantially pure silver-metal nanoparticles. Preferably, the vehicle for the silver nanoparticles will dissolve no more than 10% by of the zinc oxide-based semiconductor film, and more preferably will dissolve no more than 2% of the zinc oxide-based semiconductor film. Solubilities can be broken into four general classes: soluble, slightly soluble, sparingly soluble, and insoluble. Sparingly soluble materials have very low solubilities such as 500 mg/l or much lower. The reported water solubility of zinc oxide ranges from 1.6 mg/l to 5 mg/l. Zinc oxide is soluble in weakly acidic solutions, such as acetic acid or dilute (0.1 M) nitric acid. Although values vary widely, the wet film thickness of an inkjet printed layer is typically less than 20 μm. In one embodiment of the invention, the silver nanoparticle solution, including the liquid carrier, is capable of dissolving from 0.1 to 500 mg/l of the zinc-oxide semiconductor material, preferably 0.5 to 5 mg/l at 25° C.

The source electrode and drain electrode can be provided by any useful means such as ink jet printing or conventional print processes such as gravure, flexography, relief printing, screen printing, and the like. The source and drain terminals may be fabricated such that they are geometrically symmetrical or non-symmetrical.

Electrical contact to the gate electrode, source, drain, and substrate may be provided in any manner, as described below, for example, metal lines or traces that provide signal paths for coupling or interconnecting, electrical circuitry.

A semiconductor material on which the silver nanoparticles are deposited must display several characteristics. In typical applications of a thin film transistor, the desire is for a switch that can control the flow of current through the device. As such, it is desired that when the switch is turned on a high current can flow through the device. The extent of current flow is related to the semiconductor charge carrier mobility. When the device is turned off, it is desired that the current flow be very small. This is related to the charge carrier concentration. Furthermore, it is desired that the device be weakly or not at all influenced by visible light. In order for this to be true, the semiconductor band gap must be sufficiently large (>3 eV) so that exposure to visible light does not cause an inter-band transition.

The semiconductor films made according to the present method exhibit a field effect electron mobility that is greater than 0.01 cm²/Vs, preferably at least 0.1 cm²/Vs, more preferably greater than 0.2 cm²/Vs. In addition, n-channel semiconductor films made according to the present invention are capable of providing on/off ratios of at least 10⁴ advantageously at least 10⁵. The on/off ratio is measured as the maximum/minimum of the drain current as the gate voltage is swept from one value to another that are representative of relevant voltages which might be used on the gate line of a display. A typical set of values would be −10V to 40V with the drain voltage maintained at 30V.

The thin film of zinc-oxide-based semiconductor can be formed by various low temperature processes, including chemical vapor deposition (CVD), atomic layer deposition (ALD), and nanoparticle-solution deposition, as described in greater detail below. A zinc-oxide-based semi-conducting material is applied, for example, in the case of nanoparticles, by inkjet printing, or spin coating. In the case of vapor-phase application, chemical vapor deposition, atomic layer deposition, or the like can be employed. Various embodiments for coating and patterning the zinc-oxide-based semiconductor film are known to the skilled artisan. Patterning may occur additively, for example, employing an inkjet process, or subtractively, for example, employing a mask in combination with an acid etch process or by using a photolithographic process. For example, a continuous semiconductor layer can be patterned by employing, in combination with a resist pattern, a fluid composition, for example an acid-etch solution, capable of removing unprotected zinc-oxide-based material.

As indicated above, the present method of making the zinc-oxide-based semiconductor thin film, for use in thin film transistors, employs a zinc-oxide-based material. The zinc-oxide-based semiconductor material, especially when in the form of nanoparticles, can contain minor amounts of other metals capable of forming semiconducting oxides such as indium, tin, or cadmium, and combinations thereof. For example, Chiang, H. Q. et al., “High mobility transparent thin-film transistors with amorphous zinc tin oxide channel layer,” Applied Physics Letters 86, 013503 (2005), discloses zinc tin oxide materials. Also, minor amounts of optional acceptor or donor dopants, preferably less than 10 weight percent, can also be included in the nanoparticles before or after deposition.

Accordingly, the term “zinc-oxide-based” refers to a composition comprising zinc oxide or a mixed metal oxide comprising zinc as one of two predominant metals in the mixed metal oxide, preferably greater than 30 percent by weight, more preferably at greater than 50 percent by weight, but allowing additives or mixtures with minor amounts of other metal oxides, which semiconductor compositions are known to the skilled artisan. However, binary- or ternary-metal containing oxide semiconductor materials comprising zinc as one of predominant metal have also been developed.

Although undoped zinc-oxide-based nanoparticles can be employed in the present invention, the resistivity of the ZnO may be enhanced by substitutional doping with an acceptor dopant such as, for example, N, B, Cu, Li, Na, K, Rb, P, As, and mixtures thereof. Alternatively, p-type zinc-oxide films can be achieved, by the use of various p-type dopants and doping techniques. For example, U.S. Pat. No. 6,610,141 B2 to White et al. discloses zinc-oxide films containing a p-type dopant, for use in LEDs (light emitting devices), LDs (laser diodes), photodetectors, solar cells or other electrical devices where both n-type and p-type materials may be required for one or more multiple p-n junctions. White et al. employ diffusion of arsenic from a GaAs substrate to produce an arsenic-doped zinc-oxide-based film. U.S. Pat. No. 6,727,522 B1 also describes various dopants for p-type zinc-oxide-based semiconductor films, in addition to n-type dopants. Electrical devices in which zinc oxide is used as the n-type semiconductor and a different metal oxide, such as copper oxide or sodium cobalt oxide, is used as a p-type metal oxide are also known, as for example, described in EP 1324398 A2. Thus, the present invention can be used to make one or more semiconductor thin films in the same electrical device having a p-n junction, either by variously doped zinc-oxide-based semiconductor thin films made by the present method or by a zinc-oxide-based semiconductor thin film in combination with one or more other metal-oxide semiconductor thin films known in the art. For example, an electrical device made according to the present invention can include a p-n junction formed using a zinc-oxide-based thin film semiconductor made by the present method in combination with a thin film semiconductor of complementary carrier type as known in the art.

The thickness of the channel layer may vary, and according to particular examples it can range from about 5 nm to about 150 nm, preferably 10 to 100 nm. The length and width of the channel is determined by the pixel size and the design rules of the system under construction. Typically, the channel width may vary from 10 to 1000 μm. The channel length may vary, and according to particular examples it can range from about 1 to about 100 μm.

The entire process of making the thin film transistor or electronic device of the present invention, or at least the production of the thin film semiconductor, can be carried out below a maximum support temperature of about 300° C., more preferably below 150° C., most preferably below about 140° C., and even more preferably below about 100° C., or even at temperatures around room temperature (about 25° C. to 70° C.). The temperature selection generally depends on the support and processing parameters known in the art, once one is armed with the knowledge of the present invention contained herein. These temperatures are well below traditional integrated circuit and semiconductor processing temperatures, which enables the use of any of a variety of relatively inexpensive supports, such as flexible polymeric supports. Thus, the invention enables production of relatively inexpensive circuits containing thin film transistors with significantly improved performance.

One embodiment of the present invention is directed to a process for fabricating a thin film transistor, preferably by organic-vapor-phase or solution-phase deposition of the semiconductor thin film onto a substrate, preferably wherein the substrate temperature is at a temperature of no more than 300° C. during the deposition. Laser annealing may also be employed to allow the semiconductor to reach higher temperatures while maintaining relatively low substrate temperatures.

As indicated above, the thin film of zinc-oxide-based semiconductor can be formed by various low temperature processes, including chemical vapor deposition (CVD), atomic layer deposition (ALD) or the deposition of a colloidal solution of nanoparticles, for example, by spin coating, extrusion coating, hopper coating, dip coating, or spray coating. In a commercial scale process, the semiconductor film can be coated on a web substrate that is later divided into individual semiconductor films. Alternately, an array of semiconductor films can be coated on a moving web. Embodiments of some of these coating techniques will now be described in greater detail.

In the case of thin film semiconductor formation using nanoparticles, a particularly preferred embodiment comprises depositing a colloidal solution of zinc-oxide-containing nanoparticles on a substrate, at a substrate temperature of 300° C. or less. Charge stabilized sols are stabilized by repulsion between particles based on like surface charges. See, for example, C. Jeffrey Brinker and George W. Scherer, The Physics and Chemistry of Sol-Gel Processing, Academic Press (New York 1989).

In one embodiment, the zinc-oxide-based nanoparticles can be the reaction product of reactants comprising an organozinc precursor compound and a basic ionic compound that form a zinc-oxide-containing material and have an average primary particle size in the range of 10 to 150 nm, preferably 20 to 100 nm. It has been found that the performance of the film may be enhanced by carefully controlling the composition of the colloidal solution. Preferably the nanoparticles are colloidally stabilized in a colloidal solution in which the level of inorganic ions in the colloidal solution is below 1 mM and the level of organic compounds, or salts thereof, is below 5 mM. Preferably, the colloidal solution of nanoparticles is applied to the substrate at a level of 0.02 to 1 g/m² of nanoparticles, by dry-weight.

The colloidal solution of zinc-oxide-based nanoparticles can be applied by various methods, including conventional coating techniques for liquids. In one embodiment, the colloidal solution of nanoparticles is applied using an inkjet printer. The inkjet printer can be a continuous or drop-on-demand inkjet printer. In a conventional inkjet printer, the method of inkjet printing a semiconductor film on a substrate element typically comprises: (a) providing an inkjet printer that is responsive to digital data signals; (b) loading a first printhead with the colloidal solution of nanoparticles; (c) printing on the substrate using the colloidal solution in response to the digital data signals; and (d) annealing the printed substrate.

The zinc-oxide-based nanoparticles can be formed from the reaction of an organometallic precursor such as zinc acetate that is hydrolyzed with a base such as potassium hydroxide. Other organometallic precursor compounds can include, for example, zinc acetylacetonate, zinc formate, zinc hydroxide, zinc chloride, zinc nitrate, their hydrates, and the like. Preferably, the organometallic precursor compound is a zinc salt of a carboxylic acid, or a hydrate thereof, more preferably zinc acetate or a hydrate thereof. Optional doping materials can include, for example, aluminum nitrate, aluminum acetate, aluminum chloride, aluminum sulfate, aluminum formate, gallium nitrate, gallium acetate, gallium chloride, gallium formate, indium nitrate, indium acetate, indium chloride, indium sulfate, indium formate, boron nitrate, boron acetate, boron chloride, boron sulfate, boron formate, and their hydrates.

After particle formation, the level of ions can be reduced, by washing, to obtain a stable dispersion. Too many ions in solution can cause a screening of the particles from each other so that the particles approach too closely leading to aggregation and thus poor dispersion. Preferably, repeated washings allow the inorganic ion level to reach the desired concentration of below 1 mM. The level of organic compounds, or salts thereof, is maintained below a level of 5 mM.

In one embodiment of the invention, the zinc-oxide-based semiconductor thin film comprises supplemental material, or a subsequent layer, formed from an overcoat solution. In particular, the semiconductor properties of the thin film can be enhanced by further steps, after applying, to a substrate, the colloidal solution of zinc-oxide-based nanoparticles, drying the coating to form a porous layer of zinc-oxide-based nanoparticles, and optionally annealing the porous layer of zinc-oxide-based nanoparticles. The optional further steps comprise applying, over the porous layer of nanoparticles, an overcoat solution comprising a soluble zinc-oxide-precursor compound that converts to zinc oxide upon annealing, to form an intermediate composite film; drying the intermediate composite film; and annealing the dried intermediate composite film at a temperature of at least 50° C., suitably up to 300° C., to produce a semiconductor film comprising zinc-oxide-based nanoparticles supplemented by additional zinc oxide material formed by the conversion of the zinc-oxide-precursor compound during the annealing of the composite film.

Preferably, in this embodiment the colloidal solution of nanoparticles is applied to the substrate at a level of 0.02 to 1 g/m² of nanoparticles, by dry-weight, and the overcoat solution is preferably applied at a level of 2×10⁻⁴ to 0.01 moles/m² of precursor compound. In such a preferred embodiment, the molar ratio of nanoparticles to theoretically converted zinc-oxide precursor compound is approximately 0.02 to 60, based on moles of ZnO and precursor compound present.

Accordingly, in one embodiment of making a thin film comprising a zinc-oxide-based semiconductor using nanoparticles of the semiconductor material, the method comprises: (a) applying, to a substrate, a seed coating comprising a colloidal solution of zinc-oxide-based nanoparticles having an average primary particle size of 5 to 200 nm; (b) drying the seed coating to form a porous layer of zinc-oxide-based nanoparticles; (c) optionally annealing the porous layer of zinc-oxide-based nanoparticles at a temperature higher than the temperature of step (a) or (b); (d) applying, over the porous layer of nanoparticles, an overcoat solution comprising a soluble zinc-oxide-precursor compound that converts to zinc oxide upon annealing, to form an intermediate composite film; (e) drying the intermediate composite film; and (f) annealing the dried intermediate composite film at a temperature of at least 50° C. to produce a semiconductor film Q comprising zinc-oxide-based nanoparticles supplemented by additional zinc oxide material formed by the conversion of the zinc-oxide-precursor compound during the annealing of the composite film. This particular type of process can be referred to as a bilayer semiconductor film.

In another coating technique, a thin film of zinc-oxide-based nanoparticles may be applied by spin coating and subsequently annealed for about 10 seconds to 10 minute, preferably 1 minute to about 5 minutes in certain instances, at a temperature of about 50 to 500° C.

In the case of forming the thin film semiconductor by chemical vapor deposition at low temperature, various methods of chemical vapor deposition (CVD) are well known in the art. Metallic-oxide chemical vapor deposition is described, for example, in U.S. Pat. No. 6,936,188 B1; U.S. Patent Application Publication No. 2005/0020035A1; and U.S. Pat. No. 6,887,736, which references are hereby incorporated by reference.

In one preferred embodiment, the semiconductor thin film layer in the present method is deposited by an atomic layer deposition (ALD) process as described below. Not only the semiconductor thin film layer can be deposition by ALD, since ALD (atomic layer deposition) is also suited for forming thin layers of metal oxides or metals in the components of electronic devices. General classes of functional materials that can be deposited with ALD include conductors, dielectrics or insulators, and semiconductors.

Advantageously, ALD steps are self-terminating and can deposit precisely one atomic layer when conducted up to or beyond self-termination exposure times. An atomic layer typically ranges from about 0.1 to about 0.5 molecular monolayers, with typical dimensions on the order of no more than a few Angstroms. In ALD, deposition of an atomic layer is the outcome of a chemical reaction between a reactive molecular precursor and the substrate. In each separate ALD reaction-deposition step, the net reaction deposits the desired atomic layer and substantially eliminates “extra” atoms originally included in the molecular precursor. In its most pure form, ALD involves the adsorption and reaction of each of the precursors in the complete absence of the other precursor or precursors of the reaction. In practice in any process it is difficult to avoid some direct reaction of the different precursors leading to a small amount of chemical vapor deposition reaction. The goal of any process claiming to perform ALD is to obtain device performance and attributes commensurate with an ALD process while recognizing that a small amount of CVD reaction can be tolerated.

In ALD applications, typically two molecular precursors are introduced into the ALD reactor in separate stages. For example, a metal precursor molecule, MLₓ, comprises a metal element, M that is bonded to an atomic or molecular ligand, L. For example, M could be, but would not be restricted to, Al, W, Ta, Si, Zn, etc. The metal precursor reacts with the substrate, when the substrate surface is prepared to react directly with the molecular precursor. For example, the substrate surface typically is prepared to include hydrogen-containing ligands, AH or the like, that are reactive with the metal precursor. Sulfur (S), oxygen (O), and Nitrogen (N) are some typical A species. The gaseous precursor molecule effectively reacts with all of the ligands on the substrate surface, resulting in deposition of a single atomic layer of the metal:

substrate-AH+MLₓ→substrate-AMLₓ₋₁+HL (1)

where HL is a reaction by-product. During the reaction, the initial surface ligands, AH, are consumed, and the surface becomes covered with AMLₓ₋₁ ligands, which cannot further react with metal precursor MLₓ. Therefore, the reaction self-terminates when all of the initial AH ligands on the surface are replaced with AMLₓ₋₁ species. The reaction stage is typically followed by an inert-gas purge stage that eliminates the excess metal precursor and the HL by-product species from the chamber prior to the separate introduction of the other precursor.

A second molecular precursor then is used to restore the surface reactivity of the substrate towards the metal precursor. This is done, for example, by removing the L ligands and re-depositing AH ligands. In this case, the second precursor typically comprises the desired (usually nonmetallic) element A (i.e., O, N, S), and hydrogen (i.e., H₂O, NH₃, H₂S). The next reaction is as follows:

substrate-A-ML+AH_{Y}→substrate-A-M-A+HL (2)

This converts the surface back to its AH-covered state. (Here, for the sake of simplicity, the chemical reactions are not balanced.) The desired additional element, A, is incorporated into the film and the undesired ligands, L, are eliminated as volatile by-products. Once again, the reaction consumes the reactive sites (this time, the L terminated sites) and self-terminates when the reactive sites on the substrate are entirely depleted. The second molecular precursor then is removed from the deposition chamber by flowing inert purge-gas in a second purge stage.

In summary, then, an ALD process requires alternating in sequence the flux of chemicals to the substrate. The representative ALD process, as discussed above, is a cycle having four different operational stages:

1. MLₓ reaction;

2. MLₓ purge;

3. AH_{y} reaction; and

4. AH_{y} purge, and then back to stage 1.

This repeated sequence of alternating surface reactions and precursor-removal that restores the substrate surface to its initial reactive state, with intervening purge operations, is a typical ALD deposition cycle. A key feature of ALD operation is the restoration of the substrate to its initial surface chemistry condition. Using this repeated set of steps, a film can be layered onto the substrate in equal metered layers that are all identical in chemical kinetics, deposition per cycle, composition, and thickness.

Self-saturating surface reactions make ALD insensitive to transport non-uniformities, which might otherwise impair surface uniformity, due either to engineering tolerances and the limitations of the flow process or related to surface topography (that is, deposition into three dimensional, high aspect ratio structures). As a general rule, a non-uniform flux of chemicals in a reactive process generally results in different completion times at different areas. However, with ALD, each of the reactions is allowed to complete on the entire substrate surface. Thus, differences in completion kinetics impose no penalty on uniformity. This is because the areas that are first to complete the reaction self-terminate the reaction; other areas are able to continue until the full treated surface undergoes the intended reaction.

Typically, an ALD process deposits about 0.1-0.2 nm of a film in a single ALD cycle (with numbered steps 1 through 4 as listed earlier). A useful and economically feasible cycle time must be achieved in order to provide a uniform film thickness in a range of about from 3 nm to 300 nm for many or most semiconductor applications, and even thicker films for other applications. Industry throughput standards dictate that substrates be processed in 2 minutes to 3 minutes, which means that ALD cycle times must be in a range from about 0.6 seconds to about 6 seconds.

An ALD process must be able to execute this sequencing efficiently and reliably for many cycles in order to allow cost-effective coating of many substrates. In an effort to minimize the time that an ALD reaction needs to reach self-termination, at any given reaction temperature, one approach has been to maximize the flux of chemicals flowing into the ALD reactor, using a so-called “pulsing” process. In the pulsed ALD process, a substrate sits in a chamber and is exposed to the above sequence of gases by allowing a first gas to enter the chamber, followed by a pumping cycle to remove that gas, followed by the introduction of a second gas to the chamber, followed by a pumping cycle to remove the second gas. This sequence can be repeated at any frequency and variations in gas type and/or concentration. The net effect is that the entire chamber experiences a variation in gas composition with time, and thus this type of ALD can be referred to as time dependent ALD. The vast majority of existing ALD processes are time dependent ALD.

Conventional ALD approaches include, for example, U.S. Pat. No. 6,821,563 entitled “GAS DISTRIBUTION SYSTEM FOR CYCLICAL LAYER DEPOSITION” to Yudovsky, hereby incorporated by reference, which describes a spatially dependent ALD processing system, under vacuum, having separate gas ports for precursor and purge gases, alternating with vacuum pump ports between each gas port. Each gas port directs its stream of gas vertically downward toward a substrate. The separate gas flows are separated by walls or partitions, with vacuum pumps for evacuating gas on both sides of each gas stream. The lower portions of the partitions are separated from the substrate surface by a distance sufficient to allow the gas streams to flow around the lower portions toward the vacuum ports after the gas streams react with the substrate surface.

In this embodiment, a rotary turntable or other transport device can be provided for holding one or more substrate wafers. With this arrangement, the substrate is shuttled beneath the different gas streams, effecting ALD deposition thereby. In one embodiment, the substrate is moved in a linear path through a chamber, in which the substrate is passed back and forth a number of times.

Another approach using continuous gas flow spatially dependent ALD is shown in U.S. Pat. No. 4,413,022 entitled “METHOD FOR PERFORMING GROWTH OF COMPOUND THIN FILMS” to Suntola et al., hereby incorporated by reference. A gas flow array is provided with alternating source gas openings, carrier gas openings, and vacuum exhaust openings. Reciprocating motion of the substrate over the array effects ALD deposition, again, without the need for pulsed operation. In the embodiment of FIGS. 13 and 14 of Suntola et al., in particular, sequential interactions between a substrate surface and reactive vapors are made by a reciprocating motion of the substrate over a fixed array of source openings. Diffusion barriers are formed by a carrier gas opening between exhaust openings.

US Patent Application Publication No. 2005/0084610 to Selitser, hereby incorporated by reference, shows an atmospheric pressure atomic layer chemical vapor deposition process. Selitser et al. state that extraordinary increases in reaction rates are obtained by changing the operating pressure to atmospheric pressure, which will involve orders of magnitude increase in the concentration of reactants, with consequent enhancement of surface reactant rates. The embodiments of Selitser et al. involve separate chambers for each stage of the process, although FIG. 10 of Selitser shows an embodiment in which chamber walls are removed. A series of separated injectors are spaced around a rotating circular substrate holder track. Each injector incorporates independently operated reactant, purging, and exhaust gas manifolds and controls and acts as one complete mono-layer deposition and reactant purge cycle for each substrate as is passes there under in the process. The spacing of the injectors is selected so that cross-contamination from adjacent injectors is prevented by purging gas flows and exhaust manifolds incorporate in each injector.

A preferred embodiment of a spatially dependent ALD process for depositing a semiconductor thin film and optionally also a dielectric layer and a conductor layer in the present invention is described in detail in commonly assigned U.S. application Ser. No. 11/392,007, filed Mar. 29, 2006 by Levy et al. and entitled, “PROCESS FOR ATOMIC LAYER DEPOSITION;” U.S. application Ser. No. 11/392,006, filed Mar. 29, 2006 by Levy et al. and entitled “APPARATUS FOR ATOMIC LAYER DEPOSITION;” U.S. application Ser. No. 11/620,744, filed Jan. 8, 2007 by Levy and entitled “DEPOSITION SYSTEM AND METHOD USING A DELIVERY HEAD SEPARATED FROM A SUBSTRATE BY GAS PRESSURE;” and U.S. application Ser. No. 11/620,740, filed Jan. 8, 2007 by Nelson et al. and entitled “DELIVERY DEVICE COMPRISING GAS DIFFUSER FOR THIN FILM DEPOSITION.” All these identified applications are hereby incorporated by reference in their entirety. In particular, U.S. Ser. No. 11/392,007 employs a novel transverse flow pattern to prevent intermixing of the continuously flowing mutually reactive gases, while U.S. Ser. No. 11/620,744 and U.S. Ser. No. 11/620,740 employ a coating head partially levitated by the pressure of the reactive gases of the process to accomplish improved gas separation.

Zinc-oxide-based materials that can be made using such an atomic layer deposition process include, but are not limited to: ZnO, InZnO and InGaZnO. Doped materials that can be made include, for example, ZnO:Al, (GaInZnO, MgₓZn₁₋ₓO, and LiZnO. It will be apparent to the skilled artisan that alloys of two, three or more metals may be deposited, compounds may be deposited with two, three or more constituents, and such things as graded films and nano-laminates may be produced as well.

For various volatile zinc-containing precursors, precursor combinations, and reactants useful in ALD thin film processes, reference is made to the Handbook of Thin Film Process Technology, Vol. 1, edited by Glocker and Shah, Institute of Physics (IOP) Publishing, Philadelphia 1995, pages B1.5:1 to B1.5:16, hereby incorporated by reference; and Handbook of Thin Film Materials, edited by Nalwa, Vol. 1, pages 103 to 159, hereby incorporated by reference, including Table V1.5.1 of the former reference.

In one particular embodiment, an ALD coating may have isolated channels through which flow: (1) inert nitrogen gas; (2) a mixture of nitrogen, air and water vapor; and (3) a mixture of active metal alkyl vapor (Me₃Al or Et₂Zn) in nitrogen. The flow rate of the active metal alkyl vapor can be controlled, for example, by bubbling nitrogen through the pure liquid (Me₃Al or Et₂Zn) contained in an airtight bubbler by means of individual mass flow control meters, and the flow of water vapor can be controlled by adjusting the bubbling rate of nitrogen passed through pure water in a bubbler.

Especially when employing an ALD technique for coating the semiconductor thin film, the resistivity of the ZnO can be enhanced by substitutional doping with an acceptor dopant made from a volatile organic compound, for example, volatile compounds comprising an acceptor dopant such as N, P, As, Li, Na, K, Cu, Ag, or mixtures thereof. Preferably, the acceptor dopant comprises a Group V element, more preferably nitrogen, for example, using an acceptor dopant precursor comprises nitrogen in the form of NO, N₂O, NO₂, or ammonia.

In order for such a gas to contain sufficient volatile materials to usefully affect the deposition process, the volatile compound must have a vapor pressure at room temperature of greater than 0.1 mm Hg, preferably greater than 1 mmHg. Such dopants are preferably present in the final semiconductor in the amount of 0.001% to 5%, more preferably 0.01% to 1%.

Another aspect of the invention relates to the process for the production of semiconductor components and electronic devices incorporating such components.

In one embodiment, a substrate is provided and a layer of the semiconductor material as described above can be applied to the substrate, electrical contacts being made to the layer. The exact process sequence is determined by the structure of the desired semiconductor component. Thus, in the production of a field effect transistor, for example, a gate electrode can be first deposited on a flexible substrate, for example a vacuum or solution deposited metal or organic conductor. The gate electrode can then be insulated with a dielectric and then source and drain electrodes and a layer of the n-channel semiconductor material can be applied on top. The structure of such a transistor and hence the sequence of its production can be varied in the customary manner known to a person skilled in the art. Thus, alternatively, a gate electrode can be deposited first, followed by a gate dielectric, then the semiconductor can be applied, and finally the contacts for the source electrode and drain electrode deposited on the semiconductor layer. A third structure could have the source and drain electrodes deposited first, then the semiconductor, with dielectric and gate electrode deposited on top.

The skilled artisan will recognize other structures can be constructed and/or intermediate surface modifying layers can be interposed between the above-described components of the thin film transistor. In most embodiments, a field effect transistor comprises an insulating layer, a gate electrode, a semiconductor layer comprising a ZnO material as described herein, a source electrode, and a drain electrode, wherein the insulating layer, the gate electrode, the semiconductor layer, the source electrode, and the drain electrode are in any sequence as long as the gate electrode and the semiconductor layer contact opposite sides of the insulating layer, and the source electrode and the drain electrode both contact the semiconductor layer.

A thin film transistor (TFT) is an active device, which is the building block for electronic circuits that switch and amplify electronic signals.

Attractive TFT device characteristics include a low voltage to turn it on, a high transconductance or (device current)/(gate) control-voltage ratio, and a high ‘on’ (Vg>0) current to ‘off’ (Vg≦0) current ratio. In one embodiment of a typical TFT structure made according to the present invention, the substrate is a polymer, such as PET, PEN, KAPTON or the like. Source and drain conducting electrodes can be patterned on the substrate. The zinc-oxide-based semiconductor is then coated, followed by a gate-insulating layer such as SiO₂ or Al₂O₃ or a solution coated polymer. Finally, a gate-conducting electrode is deposited on the gate-insulating layer. One of skill in the art will recognize that this is one of many possible TFT fabrication schemes.

In the operation of such a TFT device, a voltage applied between the source and drain electrodes establishes a substantial current flow only when the control gate electrode is energized. That is, the flow of current between the source and drain electrodes is modulated or controlled by the bias voltage applied to the gate electrode. The relationship between material and device parameters of the zinc-oxide-based semiconductor TFT can be expressed by the approximate equation (see Sze in Semiconductor Devices—Physics and Technology, John Wiley & Sons (1981)):

$${I}_{d} = \frac{W}{2 L} μ {C ( {V}_{g} - {V}_{th} )}^{2}$$

where I_{d} is the saturation source-drain current, C is the geometric gate capacitance, associated with the insulating layer, W and L are physical device dimensions, μ is the carrier (hole or electron) mobility in the zinc-oxide-based semiconductor, and V_{g} is the applied gate voltage, and Vₜₕ is the threshold voltage. Ideally, the TFT allows passage of current only when a gate voltage of appropriate polarity is applied. However, with zero gate voltage, the “off” current between source and drain will depend on the intrinsic conductivity a of the zinc-oxide-based semiconductor,

σ=nqμ

where n is the charge carrier density and q is the charge, so that

(I_{sd})=σ(Wt/L)V_{sd}@Vg=0

wherein t is the zinc-oxide-based semiconductor layer thickness and V_{sd} is the voltage applied between source and drain. Therefore, for the TFT to operate as a good electronic switch, e.g. in a display, with a high on/off current ratio, the semiconductor needs to have high carrier mobility but very small intrinsic conductivity, or equivalently, a low charge carrier density. On/off ratios>10⁴ are desirable for practical devices.

The TFT structure described herein includes a transparent zinc-oxide-based semiconductor with conducting electrodes, source and drain, for injecting a current into the zinc-oxide-based semiconductor and a capacitance charge injection scheme for controlling and/or modulating the source-drain current. One particularly attractive application of zinc-oxide-based semiconductor TFT's is in the drive circuits for displays on flexible, polymer substrates. Zinc oxide semiconductor transistors and/or transistor arrays are useful in applications including, but not limited to, flat panel displays, active matrix imagers, sensors, rf price labels, electronic paper systems, rf identification tags and rf inventory tags.

For ease of understanding, the following terms used herein are described below in more detail:

“Enhancement-mode transistor” means a transistor in which there is negligible off-current flow, relative to on-current flow, between a source and a drain at zero gate voltage. In other words, the transistor device is “normally off.” In contrast, a depletion-mode transistor is “normally on” meaning that more than a substantially negligible current flows between a source and a drain at zero gate voltage. Enhancement is typically preferred.

“Gate” generally refers to the insulated gate terminal of a three terminal FET when used in the context of a transistor circuit configuration.

“Substantially transparent” generally denotes a material or construct that does not absorb a substantial amount of light in the visible portion (and/or infrared portion in certain variants) of the electromagnetic spectrum.

As used herein, “a” or “an” or “the” are used interchangeably with “at least one,” to mean “one or more” of the element being modified.

As used herein, the terms “over,” “above,” and “under,” and the like, with respect to layers in the thin film transistor, refer to the order of the layers, wherein the thin film semiconductor layer is above the gate electrode, but do not necessarily indicate that the layers are immediately adjacent or that there are no intermediate layers.

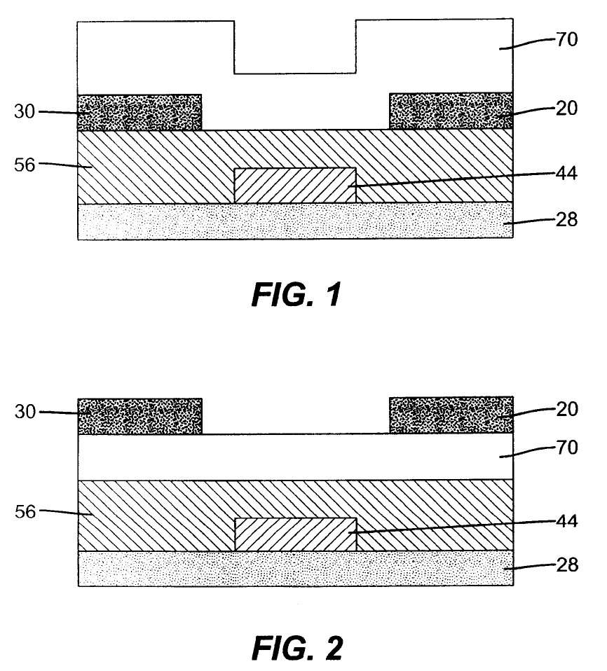

In the descriptions of FIGS. 1 to 4, the descriptors “top” and “bottom” refer to the disposition of the contact with respect to the semiconductor, with “bottom” representing closer to the substrate and “top” representing further from the substrate. These structures will be described further.

“Vertical” means substantially perpendicular to the surface of a substrate.

The preceding term descriptions are provided solely to aid the reader, and should not be construed to have a scope less than that understood by a person of ordinary skill in the art or as limiting the scope of the appended claims.

Disclosed herein are enhancement-mode, field effect transistors wherein at least a portion of the transistor structure may be substantially transparent. Devices that include the transistors and methods for making the transistors are also disclosed.

Zinc-oxide materials can be made into substantially transparent films. Accordingly, an optional characteristic of a transistor structure according to the present invention is that selected embodiments of the construct, or a subset thereof that include the semiconductor channel layer and the gate insulator layer, may exhibit an optical transmission of at least about 90%, more particularly at least about 95%, across the visible portion (and/or infrared portion in certain variants) of the electromagnetic spectrum. Each of the additional components of the structure (i.e., substrate, gate electrode, source/drain terminals) may be optionally opaque or substantially transparent depending upon the desired end use of the transistor. In certain embodiments, the transistor structure as a whole (and/or individual components of the transistor) may exhibit an optical transmission of at least about 50%, more particularly at least about 70%, and most particularly at least about 90%, across the visible portion (and/or infrared portion in certain variants) of the electromagnetic spectrum.

Because of the optional transparency, transistors made according to the present invention may be advantageously included in optoelectronic display devices as switches coupled to at least one display element, as described in greater detail below.

A further feature of the FET disclosed herein is that it may easily be fabricated as a thin film transistor (TFT) at relatively low processing temperatures (e.g., preferably not exceeding about 300° C.).

Cross-sectional views of typical solution deposited thin film transistors are shown in FIGS. 1 to 4. For example, FIG. 1 illustrates a typical bottom contact configuration, and FIG. 2 illustrates a typical top contact configuration.

Each thin film transistor (TFT) in the embodiments of FIGS. 1 and 2 contains a source electrode 20, a drain electrode 30, a gate electrode 44, a gate dielectric 56, a substrate 28, and the semiconductor 70 made according to the invention in the form of a film connecting the source electrode 20 to drain electrode 30. When the TFT operates in an enhancement-mode, the charges injected from the source electrode into the semiconductor are mobile and a current flows from source to drain, mainly in a thin channel region within about 100 Angstroms of the semiconductor-dielectric interface. See A. Dodabalapur, L. Torsi H. E. Katz, Science 1995, 268, 270, hereby incorporated by reference. In the configuration of FIG. 1, the charge need only be injected laterally from the source electrode 20 to form the channel. In the absence of a gate field the channel ideally has few charge carriers; as a result there is ideally no source-drain conduction when the device is in off mode.

The off current is defined as the current flowing between the source electrode 20 and the drain electrode 30 when charge has not been intentionally injected into the channel by the application of a gate voltage. This occurs for a gate-source voltage more negative, assuming an n-channel, than a certain voltage known as the threshold voltage. See Sze in Semiconductor Devices—Physics and Technology, John Wiley & Sons (1981), pages 438-443. The on current is defined as the current flowing between the source electrode 20 and the drain electrode 30 when charge carriers have been accumulated intentionally in the channel by application of an appropriate voltage to the gate electrode 44, and the channel is conducting. For an n-channel accumulation-mode TFT, this occurs at gate-source voltage more positive than the threshold voltage. It is desirable for this threshold voltage to be zero, or slightly positive, for n-channel operation. Switching between on and off is accomplished by the application and removal of an electric field from the gate electrode 44 across the gate dielectric 56 to the semiconductor-dielectric interface, effectively charging a capacitor.

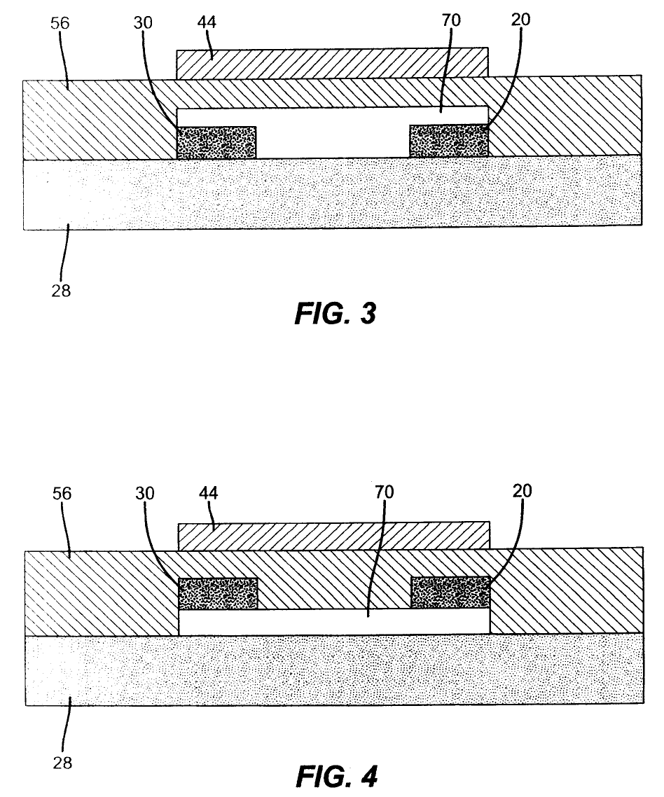

The specific examples of transistor configurations described herein are for illustrative purposes and should not be considered as limiting the scope of the appended claims. For example, a further (third) specific transistor structure is shown in FIG. 3, in which a third variation of a TFT structure includes an insulating glass substrate 28 upon which is disposed a source electrode 20 and a drain electrode 30. A semiconductor film 70 is provided such that contact between the source and drain electrodes is made. A gate electrode 44 is disposed on the top surface (from a vertical perspective) of the gate dielectric 56. In other words, the gate electrode 44 and the semiconductor film 70 are provided on opposing surfaces of the gate dielectric 56.

The TFT structure of FIG. 3 is fabricated, for example, by depositing and patterning a film that defines the source electrode 20 and the drain electrode 30. For instance, a silver nanoparticle source/drain electrode film may be printed onto the glass substrate 28 and subsequently annealed. The semiconductor film 70 may then be deposited and patterned over the source electrode 20, the drain electrode 30, and the substrate 28. For example, a ZnO-based film may be deposited, and then patterned via photolithography or solution patterning during deposition.

Subsequently, the gate dielectric 56 may then be deposited and patterned over the semiconductor film 70. For example, a 2000-Angstrom Al₂O₃ film may be deposited by a CVD or ALD process, and then patterned via photolithography. Vias (not shown) may be formed through the gate dielectric 56 to electrically connect to the source electrode 20 and the drain electrode 30. The Al₂O₃ film could optionally be annealed. The gate electrode 44 may then be deposited and patterned over the gate dielectric 56. For example, a 2000 Angstrom ITO or metal film may be deposited and/or patterned.

Yet a fourth variation of a TFT structure is shown in FIG. 4. This TFT structure includes a glass substrate 28 upon which is disposed a semiconductor channel layer 70 made according to the present invention. A source electrode 20 and a drain electrode 30 are provided on a surface of the semiconductor channel layer 70 opposing the surface that is adjacent to the glass substrate 28. A gate dielectric 56 is disposed over the semiconductor channel layer 70, the source electrode 20, and the drain electrode 30. A gate electrode 44 is disposed on the top surface (from a vertical perspective) of the gate dielectric 56. In other words, the gate electrode 44 and the semiconductor channel layer 70 are provided on opposing surfaces of the gate dielectric 56.

The TFT structure of FIG. 4 may be fabricated; for example, by the deposition and patterning of a film that defines the semiconductor channel layer 70. The source electrode 20 and the drain electrode 30 may then be deposited and patterned. For example, a silver nanoparticle source/drain electrode film may be deposited by solution deposition in the desired pattern and subsequently annealed. Subsequently, the gate dielectric 56 may then be deposited and patterned over the semiconductor channel layer 70, the source electrode 20, and the drain electrode 30. For example, a 2000 Angstrom dielectric may be deposited and patterned or selectively deposited. Vias (not shown) may be formed through the gate dielectric 56 to electrically connect to the source electrode 20 and the drain electrode 30. The gate electrode 44 may then be deposited and patterned over the gate dielectric 56. For example, a 2000 Angstrom ITO or metal film may be deposited and/or patterned

Alternatively, the contacts in the above configuration of FIG. 4 may be made by selectively doping the ends of the semiconductor channel layer with In, Al, Ga, or any other suitable n-type dopant.

Having illustrated and described the principles of the disclosed TFT transistor devices and methods with reference to several embodiments, it should be apparent that these TFT devices and methods may be modified in arrangement and detail without departing from such principles.

A support can be used for supporting the TFT during manufacturing, testing, and/or use. The skilled artisan will appreciate that a support selected for commercial embodiments may be different from one selected for testing or screening various embodiments. In some embodiments, the support does not provide any necessary electrical function for the TFT. This type of support is termed a “non-participating support” in this document. Useful materials can include organic or inorganic materials. For example, the support may comprise inorganic glasses, ceramic foils, polymeric materials, filled polymeric materials, coated metallic foils, acrylics, epoxies, polyamides, polycarbonates, polyimides, polyketones, poly(oxy-1,4-phenyleneoxy-1,4-phenylenecarbonyl-1,4-phenylene) (sometimes referred to as poly(ether ether ketone) or PEEK), polynorbornenes, polyphenyleneoxides, poly(ethylene naphthalenedicarboxylate) (PEN), poly(ethylene terephthalate) (PET), poly(ether sulfone) (PES), poly(phenylene sulfide) (PPS), and fiber-reinforced plastics (FRP). Flexible substrates can also be thin metal foils such as stainless steel provided they are coated with an insulating layer to electrically isolate the thin film transistor.

A flexible support is used in some embodiments. This allows for roll processing, which may be continuous, providing economy of scale and economy of manufacturing over flat and/or rigid supports. The flexible support chosen preferably is capable of wrapping around the circumference of a cylinder of less than about 50 cm diameter, more preferably 25 cm diameter, most preferably 10 cm diameter, without distorting or breaking, using low force as by unaided hands. The preferred flexible support may be rolled upon itself.

If flexibility is not a concern, then the substrate may be a wafer or sheet made of materials including glass and silicon.

The thickness of the substrate may vary, and according to particular examples it can range from about 20 μm to about 1 cm.

In some embodiments, the support is optional. For example, in a top construction as in FIG. 2, when the gate electrode and/or gate dielectric provides sufficient support for the intended use of the resultant TFT, the support is not required. In addition, the support may be combined with a temporary support. In such an embodiment, a support may be detachably adhered or mechanically affixed to the support, such as when the support is desired for a temporary purpose, e.g., manufacturing, transport, testing, and/or storage. For example, a flexible polymeric support may be adhered to a rigid glass support, from which support could be removed.

The gate electrode can be any useful conductive material. A variety of gate materials known in the art, are also suitable, including metals, degenerately doped semiconductors, conducting polymers, and printable materials such as carbon ink, silver-epoxy, or sinterable metal nanoparticle suspensions. For example, the gate electrode may comprise doped silicon, or a metal, such as aluminum, chromium, gold, silver, nickel, copper, tungsten, palladium, platinum, tantalum, and titanium. Gate electrode materials can also include transparent conductors such as indium-tin oxide (ITO), ZnO, SnO₂, or In₂O₃. Conductive polymers also can be used, for example polyaniline, poly(3,4-ethylenedioxythiophene)/poly(styrene sulfonate) (PEDOT:PSS). In addition, alloys, combinations, and multilayers of these materials may be useful.

The thickness of the gate electrode may vary, and according to particular examples it can range from about 50 to about 1000 nm. The gate electrode may be introduced into the structure by chemical vapor deposition, sputtering, evaporation and/or doping, or solution processing.

In some embodiments, the same material can provide the gate electrode function and also provide the support function of the support. For example, doped silicon can function as the gate electrode and support the TFT.

The gate dielectric is provided in contact with the gate electrode. This gate dielectric electrically insulates the gate electrode from the balance of the TFT device. Thus, the gate dielectric comprises an electrically insulating material. The gate dielectric should have a suitable dielectric constant that can vary widely depending on the particular device and circumstance of use. For example, a dielectric constant from about 2 to 100 or even higher is known for a gate dielectric. Useful materials for the gate dielectric may comprise, for example, an inorganic electrically insulating material. The gate dielectric may comprise a polymeric material, such as polyvinylidenedifluoride (PVDF), cyanocelluloses, polyimides, etc. The gate dielectric may comprise a plurality of layers of different materials having different dielectric constants.

Specific examples of materials useful for the gate dielectric include strontiates, tantalates, titanates, zirconates, aluminum oxides, silicon oxides, tantalum oxides, titanium oxides, silicon nitrides, barium titanate, barium strontium titanate, barium zirconate titanate, zinc selenide, and zinc sulfide. In addition, mixed oxides, alloys, combinations, and multilayers of these examples can be used for the gate dielectric. Of these materials, aluminum oxides, silicon oxides, and zinc selenide are preferred. In addition, polymeric materials such as polyimides, polyvinyl alcohol, poly(4-vinylphenol), polyimide, and poly(vinylidene fluoride), polystyrene and substituted derivatives thereof, poly(vinyl naphthalene) and substituted derivatives, and poly(methyl methacrylate) and other insulators having a suitable dielectric constant may be employed.

The gate dielectric can be provided in the TFT as a separate layer, or formed on the gate such as by oxidizing the gate material to form the gate dielectric. The dielectric layer may comprise two or more layers having different dielectric constants. Such insulators are discussed in U.S. Pat. No. 5,981,970 hereby incorporated by reference and copending U.S. patent application Ser. No. 11/088,645, hereby incorporated by reference. Gate insulator materials typically exhibit a band-gap of greater than about 5 eV.

The thickness of the gate insulator layer may vary, and according to particular examples it can range from about 10 to about 300 nm. The gate dielectric layer may be introduced into the structure by techniques such as chemical vapor deposition, sputtering, atomic layer deposition, evaporation, or solution deposition.

The gate dielectric separates the source electrode and drain electrode from the gate electrode, while the zinc-oxide-based semiconductor layer can be over or under the source electrode and drain electrode.

Electrical contact to the gate electrode, source, drain and substrate may be provided in any manner. For example, metal lines, traces, wires, interconnects, conductors, signal paths and signaling mediums may be used for providing the desired electrical connections. The related terms listed above, are generally interchangeable, and appear in order from specific to general. Metal lines, generally aluminum (Al), copper (Cu) or an alloy of Al and Cu, are typical conductors that provide signal paths for coupling or interconnecting, electrical circuitry. Conductors other than metal may also be utilized.

In cases where another layer covers the electrical contact of interest, connection to the electrical contact can be made by creating a “via” that penetrates to the contact. Such vias can be made by convenient patterning operations such as lithography, etching, patterned deposition, or laser based processes.

An illustrative n-channel operation of the transistor involves applying a positive voltage to the gate electrode, grounding the source, and applying a positive voltage to the drain. For example, a voltage of about 5 to about 40 V may be applied to the gate electrode and the drain during operation. The threshold voltage may range from about −minus 10 to about 20 V, although devices can operate with larger ranges. Electrons flow from the source, along the semiconductor thin film, and out of the transistor through the drain. The effective mobility of the electrons may vary depending upon the specific structure, but typically should be greater than 0.01 cm² V⁻¹ s⁻¹ for useful practical applications. Simply by removing the positive voltage applied to the gate electrode turns the transistor off when the transistor is an enhancement-mode transistor.

Devices in which the n-channel semiconductor films made according to the present invention are useful include especially thin film transistors (TFTs). Also, such films can be used in various types of devices having p-n junctions, such as described on pages 13 to 15 of US Patent Application Publication No. 2004/0021204 A1 to Liu, hereby incorporated by reference.

Electronic devices in which TFTs and other devices are useful include, for example, more complex circuits, e.g., shift registers, integrated circuits, logic circuits, smart cards, memory devices, radio-frequency identification tags, backplanes for active matrix displays, active-matrix displays (e.g. liquid crystal or OLED), solar cells, ring oscillators, and complementary circuits, such as inverter circuits, for example, in combination with other transistors made using available p-type organic semiconductor materials such as pentacene. In an active matrix display, a transistor made according to the present invention can be used as part of voltage hold circuitry of a pixel of the display. In such devices, the TFTs are operatively connected by means known in the art.

One example of a microelectronic device is an active-matrix liquid-crystal display (AMLCD). One such device is an optoelectronic display that includes elements having electrodes and an electro-optical material disposed between the electrodes. A connection electrode of the transparent transistor may be connected to an electrode of the display element, while the switching element and the display element overlap one another at least partly. An optoelectronic display element is here understood to be a display element whose optical properties change under the influence of an electrical quantity such as current or voltage such as, for example, an element usually referred to as liquid crystal display (LCD). The presently detailed transistor has sufficient current carrying capacity for switching the display element at such a high frequency that the use of the transistor as a switching element in a liquid crystal display is possible. The display element acts in electrical terms as a capacitor that is charged or discharged by the accompanying transistor. The optoelectronic display device may include many display elements each with its own transistor, for example, arranged in a matrix. Certain active matrix pixel designs, especially those supplying a display effect that is current driven, may require several transistors and other electrical components in the pixel circuit.

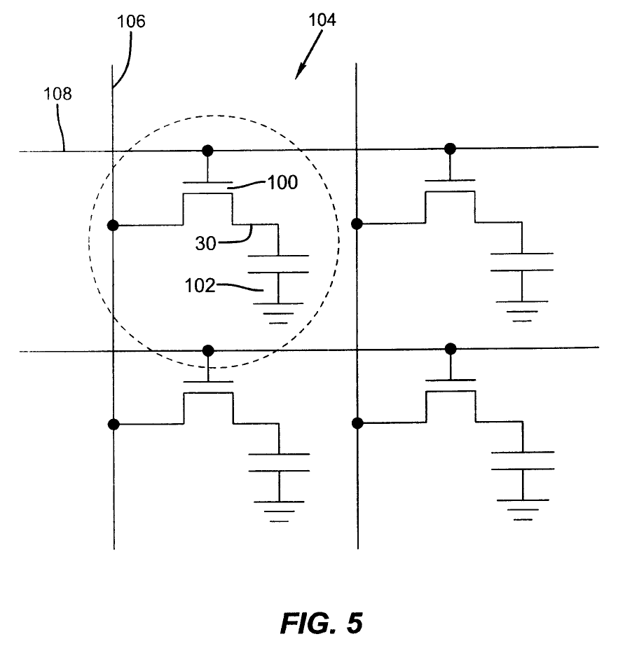

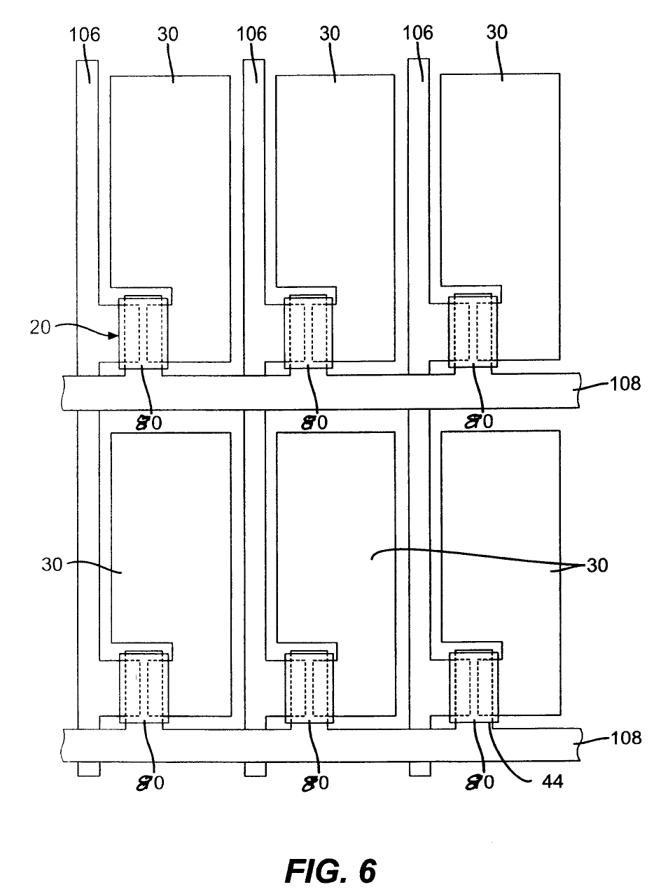

One specific example of a basic AMLCD cell circuit is depicted in FIG. 5. The AMLCD cell circuit includes a transistor 100 as presently described, and an LCD pixel 102 electrically coupled thereto. The transistor 100 and the LCD pixel 102 together form a transistor/pixel cell 104. In the arrangement shown, the transistor 100 is electrically coupled to the LCD pixel 102 via the drain electrode 30. The gate electrode of the transistor 100 is electrically coupled to a row or control line 108 (also referred to as a select or gate line) that receives on/off input for the transistor 100. The source electrode of the transistor 100 is electrically coupled to a column or data line 106 that receives a signal for controlling the LCD pixel 102. Each LCD pixel 102 can also be viewed as a capacitor representing the capacitance according to display design.

FIG. 6 shows a typical pixel layout in which data lines 106 lead to individual source electrodes 20, control lines 108 lead to individual gate electrodes 44, thin film transistors 80, and drain electrodes 30 each forming a pixel conductor pad.

Advantages of the invention will be demonstrated by the following examples, which are intended to be exemplary.

### EXAMPLES

### A. Material Synthesis

A ZnO Seed Layer Formulation-1 (SLF-1) was prepared as follows. (All reagents were obtained from the Aldrich Chemical Company.) To a 40 mL amber glass bottle with screw cap was added 0.015 moles zinc acetate (99.99%) in 20 mL of methanol. With stirring, 270 μL of 18.5 MΩ water was added. The above solution was held, with stirring, at 60 C in a constant temperature water bath for 10 minutes.

A solution of 7.68 mL of 2.93M KOH in methanol plus 4.32 mL of methanol was then added drop wise, at a rate of 1 mL/minute, to the above solution at 60° C. Following the completion of the base addition, the solution is kept stirring at 60° C. for 20 hours.

Following the completion of the reaction, 15 mL of the above solution were extracted and repeatedly washed by centrifugation followed by redispersion in methanol. The final wash consisted of redispersal in a solution of 1 part methanol and 3 parts hexanes, again followed by centrifugation. The final material was then redispersed in ethanol.

A typical sample of such a seed solution shows a primary particle size of approximately 80 nm as measured with UPA. The sample may also contain some particle aggregates of low number, leading to and apparent bimodal particle distribution.

### B. Device Preparation

Unless otherwise stated, the TFT's in the examples were made employing a gate and dielectric structure in a top contact structure (FIG. 2) consisting of a heavily doped n-type silicon gate on which was grown a thermal oxide to a thickness of 1850 Angstroms. Prior to deposition of any semiconductor layers on top of the thermal oxide, this substrate (silicon wafer or glass) was washed for 10 minutes by treating with a solution of 70% sulfuric acid and 30% of a 30% solution of hydrogen peroxide maintained at approximately 100° C. After washing, semiconductor layers were applied as shown in the following examples. After the semiconductor layers were applied, metal contacts representing the source and drain electrodes were formed, in the comparative examples, from silver using vacuum evaporation through a shadow mask, as described in detail in the Comparative Examples below. In the inventive examples, silver nanoparticles were applied by inkjet as described in detail in the Examples.

Typical electrodes were of a size leading to a channel that was 480 micrometers wide by about 50 micrometers long, although due to small channel length variations mobilities were calculated using individually measured channel lengths. Devices were then tested for transistor activity.

### C. Device Measurement and Analysis

Electrical characterization of the fabricated devices was performed with a Hewlett Packard HP 4156 parameter analyzer. Device testing was done in air in a dark enclosure.

The results were averaged from several devices. For each device, the drain current (Id) was measured as a function of source-drain voltage (Vd) for various values of gate voltage (Vg). Furthermore, for each device the drain current was measured as a function of gate voltage for various values of source-drain voltage. For most devices, Vg was swept from −10 V to 40 V for each of the drain voltages measured, typically 5 V, 20 V, and 35 V, and 50 V. Mobility measurements were taken from the 35V sweep.

Parameters extracted from the data include field-effect mobility (μ), threshold voltage (Vth), subthreshold slope (S), and the ratio of Ion/Ioff for the measured drain current. The field-effect mobility was extracted in the saturation region, where Vd>Vg−Vth. In this region, the drain current is given by the equation (see Sze in Semiconductor Devices—Physics and Technology, John Wiley & Sons (1981)):

$${I}_{d} = \frac{W}{2 L} μ {{C}_{ox} ( {V}_{g} - {V}_{th} )}^{2}$$

where, W and L are the channel width and length, respectively, and Cₒₓ is the capacitance of the oxide layer, which is a function of oxide thickness and dielectric constant of the material. Given this equation, the saturation field-effect mobility was extracted from a straight-line fit to the linear portion of the √I_{d} versus Vg curve. The threshold voltage, Vₜₕ, is the x-intercept of this straight-line fit.

The log of the drain current as a function of gate voltage was plotted. Parameters extracted from the log I_{d} plot include the on/Ioff ratio. The Iₒₙ/I_{off} ratio is simply the ratio of the maximum to minimum drain current, and S is the inverse of the slope of the I_{d} curve in the region over which the drain current is increasing (i.e., the device is turning on).

### Comparative Example 1

The semiconductor layer was applied using a coating solution prepared by diluting the above seed formulation, SLF-1, to 1.3% in ethanol. The above solution was applied to the substrate by spin coating at a rate of 2000 rpm. After the spin coating, the samples were annealed for 10 minutes at 20° C. in dry air.

Following the anneal, a precursor layer consisting of 0.175M Zn—Ac in methanol plus 108 μL of 18.5 MΩ water was spun on to the substrate at 2000 rpm. This layer was then annealed at 200° C. for 10 minutes in dry air. After this process, silver contacts were applied by evaporation. The devices were tested and the results are shown in Table 1 below.

TABLE 1

| | Ag Anneal Temperature | |
|---|---|---|
| Sample | (° C.) | Extracted Mobility |
| C-1 | 60 | No detectable activity |
| C-2 | 60 | No detectable activity |
| C-3 | 104 | No detectable activity |
| C-4 | 151 | No detectable activity |
| C-5 | 250 | No detectable activity |
| C-6 | 60 | No detectable activity |

As can be seen in Table 1, the evaporation of silver contacts on to the current ZnO device film formulation does not result in any detectable device activity.

### Example 2

In this inventive example, the semiconductor layer was applied as in Comparative Example 1 and then inkjet printed silver nanoparticles were used to make the source and drain for the transistor.

Inkjet printing experiments were performed using a system consisting of a sample platen supported by a set of X-Y translation stages, piezoelectric demand-mode printheads supported by a Z translation stage, and software to control these components. The printheads of this inkjet system are suited to dispense droplets in the 20-60 picoliter range. Approximately 2 cc of the fluid to be printed is placed in a sample cartridge which is then screwed to the printing fixture. The printhead is primed with ink using pressurized nitrogen. A TENCOR profilometer was used to measure the printed film thicknesses of a series of calibration samples. The drop volume was calculated by best-fit linear regression in a simple model relating number of drops fired, ink concentration, and printed film thickness.

A first zinc oxide TFT Sample 2-1 was prepared as follows. A first zinc oxide film was prepared according to the procedure described above for Comparative Example 1. The sample was then placed on a sample holder at 70° C. An ink cartridge was filled with an aqueous solution containing 20 wt % of ca. 70 nm silver nanoparticles. A pair of parallel silver lines was printed directly on the zinc oxide layer and heated for 30 minutes at 150° C. in air to form a conductive film having good electrical contact with the semiconducting layer.

For a second zinc oxide TFT Sample 2-2, silver contacts were prepared from ca. 30 nm silver nanoparticulates, a commercially available silver dispersion purchased from Cabot (Albuquerque, N. Mex.), diluted 1:1 with water. This zinc oxide TFT was prepared in identical manner as for the device Sample 2-1, with the exception that the ink cartridge contained a different variety of silver nanoparticles.

The Samples were tested and the results shown in Table 2 below.

TABLE 2

| Sample ID | Mobility (cm²/Vs) |
|---|---|
| 2-1 | 0.17 |
| 2-2 | 0.14 |

The above results using silver nanoparticles according to the present invention showed mobilities necessary for effective device activity, compared to the use of evaporated silver in which no detectable activity was found.

### Example 3

This Example shows a variety of inkjet printed silver contact electrodes applied to a variety of inkjet-printed ZnO semiconductor films in thin film transistors made according to the present invention. In these examples, the ZnO semiconductor films were printed using the same inkjet printer as used for the making the source and drain from the silver nanoparticles.

The variety of inkjet-printed ZnO-semiconductor films were prepared as follows. A 30 mm square sample of a silicon wafer was cleaned according to the procedure described above and placed on the printhead stage. A 3.31 wt % dispersion of charge stabilized ZnO nanoparticles was diluted with ethanol to 1.3 wt %, and an ink cartridge was filled with the resulting fluid. By overlaying drops at different drop spacing, a set of ZnO nanoparticle films with varying film thickness were obtained. The samples were heated for 10 minutes at 200° C. in air. A 0.175 molar zinc acetate solution in methanol was then printed on top of the printed ZnO films. By overlaying drops at different drop spacing, the molar ratio of zinc acetate to zinc oxide varied from patch to patch. The samples were heated for 10 minutes at 200° C. in air.

Silver contacts were prepared according to the procedure described for Sample 2-2. The ZnO thickness and charge mobility results are summarized in Table 3 below. The precursor overcoat thickness in Table 3 is based on complete conversion of zinc acetate to zinc oxide and is calculated from the number of drops per printed area, drop volume, and the zinc acetate concentration.

TABLE 3

| | ZnO seed | Overcoat | Total | |
|---|---|---|---|---|
| | thickness | thickness | thickness | Mobility |
| Sample No. | (nm) | (nm) | (nm) | (cm²/Vs) |
| 3-1 | 103 | 36.5 | 140 | 0.002 |
| 3-2 | 62 | 36.5 | 99 | 0.062 |
| 3-3 | 33.5 | 36.5 | 70 | 0.091 |
| 3-4 | 11 | 36.5 | 48 | 0.024 |
| 3-5 | 8.4 | 36.5 | 45 | 0.047 |
| 3-6 | 103 | 113 | 216 | 0.005 |
| 3-7 | 62 | 113 | 175 | 0.018 |
| 3-8 | 26.8 | 113 | 140 | 0.109 |
| 3-9 | 21.6 | 113 | 135 | 0.024 |
| 3-10 | 33.5 | 9.2 | 43 | 0.035 |
| 3-11 | 26.8 | 9.2 | 36 | 0.039 |
| 3-12 | 11 | 9.2 | 20 | 0.098 |
| 3-13 | 8.4 | 9.2 | 18 | 0.015 |
| 3-14 | 62 | 23.5 | 86 | 0.052 |
| 3-15 | 33.5 | 23.5 | 57 | 0.117 |
| 3-16 | 21.6 | 23.5 | 45 | 0.037 |
| 3-17 | 11 | 23.5 | 35 | 0.065 |
| 3-18 | 8.4 | 23.5 | 32 | 0.017 |

The above results using silver nanoparticles according to the present invention, using a different method of making the ZnO thin film than Example 2, again showed mobilities necessary for effective device activity, compared to the use of evaporated silver in which no detectable activity was found.

### Comparative Example 4

In this example, TFT structures were prepared using an atmospheric pressure CVD coating head to deposit the zinc oxide semiconductor film.

The sample substrate consisted of a heavily doped silicon wafer, acting as the gate, on which was grown 1850 Å of a thermal silicon oxide, active as the gate dielectric. These samples then received the APCVD deposition of zinc oxide.

The APCVD deposition was accomplished by the use of a homemade deposition head that allowed two linear gas streams to mix and then be immediately directed toward a substrate. The linear gas streams and the resulting linear stream directed to the substrate were 2 inches in width.

The first stream contained diethylzinc vapor diluted in argon. This stream was created by bubbling 5 sccm of argon through diethylzinc at room temperature, and then diluting this stream with 4000 sccm of argon. The second stream contained air as the oxidizer and was also diluted in argon. This stream was created by mixing 5 sccm of air with 100 sccm of argon. The deposition head was maintained between 30 and 40° C. and the substrate was maintained at 200° C. The deposition was accomplished by allowing the reactive gases to flow at the substrate for 1 minute.

After this process, silver contacts were applied by evaporation. This structure was tested for transistor activity as described above, but did not result in any detectable device activity.

### Example 5

In this example, TFT structures were prepared in the same manner as for Comparative Example 4, except inkjet printed silver nanoparticles were employed in making the source and drain. After deposition of the zinc oxide film, a photoresist pattern was prepared on the ZnO coating containing pairs of open rectangular areas, which defined the desired shape and arrangement of the source and drain regions of the TFTs. The ZnO coating between a specific pair of open rectangular areas was therefore covered by the photoresist material, which defined the shape and location of the channel of that particular TFT. Using the inkjet printing system described in Example 2, the substrate was placed on the sample holder at 60° C., and a top-view camera was used to locate the open rectangular areas on the ZnO coating. A commercially available silver dispersion purchased from Cabot (Albuquerque, N. Mex.), was diluted 1:1 with water and deposited specifically onto the open rectangular areas on the ZnO coating. The resulting sample was heated for 30 minutes at 130° C. in air, completing the TFT structure.) This procedure produced devices with a channel width of 480 micrometer and a channel length of 48 micrometer. This structure was tested for transistor activity as described above, indicating the saturation field-effect mobility for the zinc-oxide-based semiconductor was 0.7 cm²/V-sec.

The above results using silver nanoparticles according to the present invention showed mobilities necessary for effective device activity, compared to the use of evaporated silver in which no detectable activity was found.

### Example 6

In this example, TFT structures were prepared in the same manner as for comparative Example 4, except a polymer was used as the dielectric layer and inkjet printed silver nanoparticles were employed in making the gate as well as the source and drain electrodes. Using the inkjet printing system described in Example 2, an ink cartridge was loaded with a silver nanoparticle dispersion containing ca. 30 nm nanoparticulates, purchased from Cabot. A clean glass substrate was placed on the sample holder at 60° C., and a pattern consisting of evenly spaced rows of silver nanoparticles was inkjet printed. Each row was approximately 190 um wide and 0.15 um thick, and the spacing between these rows was approximately 800 um. The resulting sample was heated at 200° C. for 10 minutes in air to form the conducting gate lines of the TFTs. Following this process, a 10% solution of a polymer dielectric dissolved in cyclohexane was spun on to the substrate at 2500 RPM, and the sample was annealed at 250° C. for 2 minutes, forming the dielectric layer of the TFTs. Ellipsometry measurements indicated the resulting film was 370 nm thick. Following the annealing, a zinc oxide film was deposited using the atmospheric CVD system described in Comparative Example 4. After this process, the sample was placed on the sample holder of the inkjet printing system described above. Using the same silver nanoparticle ink employed in making the gate, the desired pattern of source and drain electrodes was printed on the sample, aligned to the gate electrodes with the aid of a top-view camera. When the printing step was completed, the sample was annealed at 200° C. for ten minutes. Devices were tested for transistor activity as described above, indicating the saturation field-effect mobility for the zinc-oxide-based semiconductor was 0.01 cm²/V-sec.

### Example 7

In this example, TFT structures were prepared using an atmospheric pressure ALD coating head to deposit an aluminum oxide dielectric film and the zinc oxide semiconductor film, and also employing inkjet printed silver nanoparticles in making the source and drain. The aluminum oxide and zinc oxide films were deposited on a heavily doped silicon wafer, which functioned as the gate electrode. The particular apparatus used to deposit these films has been described in more detail in U.S. patent application Ser. No. 11/392,006, filed Mar. 29, 2006 by Levy et al, and entitled “APPARATUS FOR ATOMIC LAYER DEPOSITION.” This coating head has isolated channels through which flow: (1) inert nitrogen gas; (2) a mixture of nitrogen and air vapor; and (3) a mixture of active metal alkyl vapor (Me₃Al or Et₂Zn) in nitrogen. The flow rate of the active metal alkyl vapor was controlled by bubbling nitrogen through the pure liquid contained in an airtight bubbler by means of individual mass flow control meters. The temperature of the coating head was maintained at 40° C. The flow rates of the individual gasses were adjusted to the settings shown in Table 4, below, and the coating process was initiated by oscillating the coating head across the substrate. The length of the reciprocation cycle was 32 mm. The rate of motion of the reciprocation cycle is 30 mm/sec.

TABLE 4

| | Me₃Al | Diethylzinc | Metal Precursor | | Water | Oxidizer | Nitrogen | |
|---|---|---|---|---|---|---|---|---|
| | Bubbler Flow | Bubbler Blow | Dilution Flow | Air Flow | Bubbler Flow | Dilution Flow | Purge Flow | |
| Layer | (sccm) | (sccm) | (sccm) | (sccm) | (sccm) | (sccm) | (sccm) | Cycles |
| Alumina film | 8 | 0 | 620 | 10 | 15 | 100 | 500 | 300 |
| ZnO film | 0 | 8 | 620 | 10 | 15 | 100 | 500 | 30 |

After deposition of the ALD films, a photoresist pattern was prepared on the ZnO coating containing pairs of open rectangular areas, which defined the desired shape and arrangement of the source and drain regions of the TFTs. The ZnO coating between a specific pair of open rectangular areas was therefore covered by the photoresist material, which defined the shape and location of the channel of that particular TFT. Using the inkjet printing system described in Example 2, the substrate was placed on the sample holder at 70° C., and a top-view camera was used to locate the open rectangular areas on the ZnO coating. A commercially available silver dispersion purchased from Cabot (Albuquerque, N. Mex.), was diluted 1:1 with water and deposited specifically onto the open rectangular areas on the ZnO coating. The resulting sample was heated for 30 minutes at 130° C. in air, completing the TFT structure. This procedure produced devices with a channel width of 480 micrometer and a channel length of 48 micrometer. Devices were tested for transistor activity as described above, indicating the saturation field-effect mobility for the zinc-oxide-based semiconductor was 2.2 cm²/V-sec.

The above examples demonstrate that the invention may be practiced with a wide range of zinc-oxide nanoparticle and silver nanoparticle applications.

### PARTS LIST

20 source electrode
28 substrate
30 drain electrode
44 gate electrode
56 gate dielectric
70 semiconductor
80 thin film transistors
100 transistor
102 LCD pixel
104 transistor/pixel cell
106 column or data line
108 row or control line

1. A method of making a thin film transistor comprising a zinc-oxide-based semiconductor, the method comprising, in any order, the following steps:
(a) forming on a substrate, at a temperature of 300° C. or less, a zinc-oxide-based semiconductor thin film, wherein the thin film is formed from a material that is the reaction product of a first reactant, an organo-zinc precursor compound comprising both zinc and organic groups, and a second reactant, an inorganic compound comprising oxygen, wherein the thin film has a thickness of 5 to 150 nm;
(b) depositing, in a pattern, a colloidal solution of substantially pure silver-metal nanoparticles having an average primary particles size of 5 to 100 nm, whereby the pattern is in the form of a source electrode and a drain electrode; and
(c) annealing at a temperature of between 100° C. and 500° C. to convert the substantially pure silver-metal nanoparticles to the source electrode and the drain electrode, having a thickness of at least 500 Angstroms, of substantially pure silver, in contact with a surface of the zinc-oxide-based semiconductor film.

2. The method of claim 1 wherein the colloidal solution of substantially pure silver-metal nanoparticles are deposited as fluid droplets by inkjet printing.

3. The method of claim 1 wherein the colloidal solution of substantially pure silver-metal nanoparticles are deposited by relief printing, gravure printing, screen printing, or by flexography in which a roller picks up a coating of the colloidal solution of substantially pure silver-metal nanoparticles and applies it on a mask.

4. The method of claim 1 wherein the colloidal solution of substantially pure silver-metal nanoparticles, after depositing and annealing, has a thickness of 0.05 micrometers to 5 micrometers.

5. The method of claim 1 wherein the colloidal solution of substantially pure silver-metal nanoparticles is aqueous with less than 50%, by weight of total liquid carrier, of an organic solvent.

6. The method of claim 1 wherein silver nanoparticle solution, including liquid carrier, is capable of dissolving from 0.1 to 500 mg/l of the zinc-oxide-based semiconductor material at 25° C.

7. The method of claim 1 wherein a second reactant comprising oxygen is an ionic base or water.

8. The method of claim 1 wherein the organozinc precursor compound is zinc acetate or diethyl zinc.

9. The method of claim 1 wherein the organozinc precursor compound is dissolved in a non-aqueous organic solvent.

10. The method of claim 1 wherein the colloidal solution of substantially pure silver-metal nanoparticles is applied by an inkjet printhead.

11. The method of claim 10 wherein comprising:
(a) providing an inkjet printhead that is responsive to digital data signals;
(b) loading a first printhead with a zinc-oxide nanoparticle solution;
(c) printing on the substrate using the zinc-oxide nanoparticle solution to form a coating for the zinc-oxide-based semiconductor thin film in response to the digital data signals;
(d) loading a second printhead with the colloidal solution of substantially pure silver-metal nanoparticles;
(e) printing over the first coating to form printed material using the colloidal solution of substantially pure silver-metal nanoparticles in response to the digital data signals; and
(f) annealing the printed material.

12. The method of claim 1 wherein the zinc-oxide-based semiconductor thin film is formed by depositing a colloidal solution of zinc-oxide-based nanoparticles on the substrate, wherein the colloidal solution of zinc-oxide-based nanoparticles are applied to the substrate at a level of 0.02 to 1 g/m² of nanoparticles, by dry-weight, and wherein the nanoparticles have an average primary particle size in the range of 10 to 150 nm and wherein the film has a thickness of 10 to 150 nm.

13. The method of claim 12 wherein the colloidal solution of zinc-oxide-based nanoparticles is applied by spin coating, extrusion coating, hopper coating, dip coating, spray coating, or inkjet printing.

14. The method of claim 1 wherein the zinc-oxide-based semiconductor thin film is formed by a chemical vapor deposition comprising the reaction of a zinc-containing precursor with an oxidizing agent.

15. The method of claim 1 wherein the zinc-oxide-based semiconductor film is formed by atomic layer deposition comprising the reaction of a zinc-containing precursor with an oxidizing agent.

16. The method of claim 1 wherein the zinc-oxide-based thin semiconductor film has a thickness of 10 to 150 nanometers.

17. The method according to claim 1, wherein the annealing is by means of a laser-annealing technique.

18. The method of claim 1 wherein the zinc-oxide-based semiconductor thin film exhibits a band gap of less than about 5 eV and exhibits a field effect electron mobility that is greater than 0.01 cm²/Vs, and the transistor has an on/off ratio of a source/drain current of at least 104.

19. The method of claim 1 wherein the zinc-oxide semiconductor thin film is an active layer in a field effect transistor comprising a dielectric layer, a gate electrode, a source electrode and a drain electrode, and wherein the dielectric layer, the gate electrode, the semiconductor thin film, the source electrode, and the drain electrode are in any sequence as long as the gate electrode and the semiconductor thin film both contact the dielectric layer, and the source electrode and the drain electrode both contact the semiconductor thin film.

20. The method of claim 1 comprising, not necessarily in the following order, the steps of:
(a) forming a layer of zinc-oxide-based material on the substrate to form a thin film of zinc-oxide-based semiconductor material, such that the semiconductor material exhibits a field effect electron mobility that is greater than 0.01 cm²/Vs;
(b) forming a spaced apart source electrode and a drain electrode, wherein the source electrode and the drain electrode are separated by, and electrically connected with, the thin film of zinc-oxide-based semiconductor material; and
(c) forming a gate electrode spaced apart from the semiconductor material.

21. An electronic device comprising a multiplicity of thin film transistors made according to claim 1, wherein the electronic device is selected from the group consisting of an integrated circuit, active-matrix display, solar cell, flat panel display, active matrix imager, sensor, and rf label containing price, identification, and/or inventory information.

22. The electronic device of claim 21 wherein the device is an optoelectronic display device comprising at least one display element coupled to a switch comprising an enhancement-mode, field effect transistor, wherein the device comprises an active-matrix display.
